(19) United States
(12) Patent Application Publication
(10) Pub. No.: US 2007/0222468 A1
(43) Pub. Date: Sep. 27, 2007

(54) High bandwidth probe system

(76) Inventor: Michael T. McTigue, Colorado Springs, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/386,624

(22) Filed: Mar. 22, 2006

(51) Int. Cl. G01R 31/02

(52) U.S. Cl. 324/762

(57) ABSTRACT

A probing system for use with a measurement device has a probe head substrate shaped to form dual cantilever members, a resistive element disposed on each cantilever member and connected to respective signal contact elements. Each resistive element is electrically connected to center conductors of respective probe cables, which are adapted for connection to the measurement device.

### BACKGROUND

Oscilloscopes are an important tool in test and debug of high frequency circuits and printed circuit boards. There are a number of high bandwidth oscilloscopes available, but the delivery of the electrical signal from the device or system under test to the oscilloscope presents a challenge. Specifically, probing systems that access and then deliver the desired electrical signal to the oscilloscope must be able to operate within the same bandwidth as the oscilloscope. As one of ordinary skill in the art appreciates, the lowest bandwidth part in the measurement system limits the entire measurement system. Specifically, a lower bandwidth probing system limits the measurement capability of the high bandwidth oscilloscope used in conjunction with the bandwidth limited probing system.

Traditional probing systems have parasitic impedances that operate to limit the bandwidth of the signal presented to the tip of the probe. In addition, the parasitic impedances also impedance load the system under test altering its behavior and precluding measurement of the system under normal operating conditions. There is a recognized need, therefore, to provide high bandwidth probes with reduced parasitic impedances suitable for use with high bandwidth measurement equipment.

### BRIEF DESCRIPTION OF THE DRAWINGS

An understanding of the present teachings can be gained from the following detailed description, taken in conjunction with the accompanying drawings of which like reference numerals in different drawings refer to the same or similar elements.

FIG. 1 is an illustration of an oscilloscope probing system.

FIG. 2 is a perspective partial cut-away view of a probe head suitable for use in the oscilloscope probing system according to the present teachings.

FIG. 3 is a perspective view of a side of the probe head opposite that of the view shown in FIG. 2.

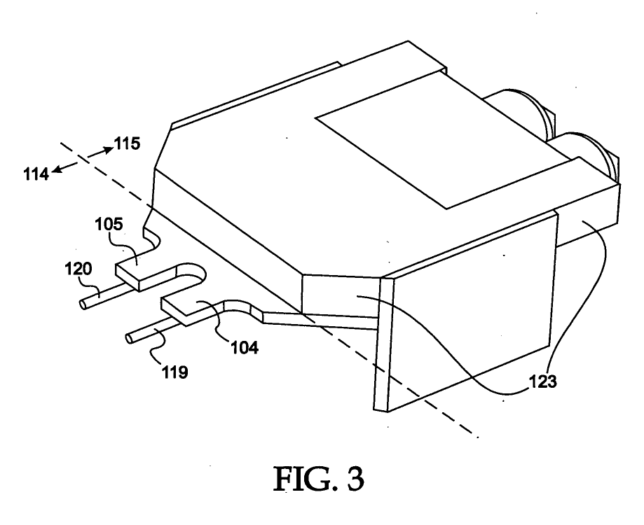

FIG. 4 is a perspective view without cut-away of the probe head of FIG. 2.

### DETAILED DESCRIPTION

In the following detailed description, for purposes of explanation and not limitation, example embodiments disclosing specific details are set forth in order to provide a thorough understanding of specific embodiments according to the present teachings. However, it will be apparent to one with ordinary skill in the art having benefit of the present disclosure that other embodiments according to the present teachings that depart from the specific details disclosed herein remain within the scope of the appended claims. Descriptions of well-known apparatus and methods may be omitted so as to not obscure the description of the example embodiments. Such methods and apparatus are clearly within the scope of the present teachings.

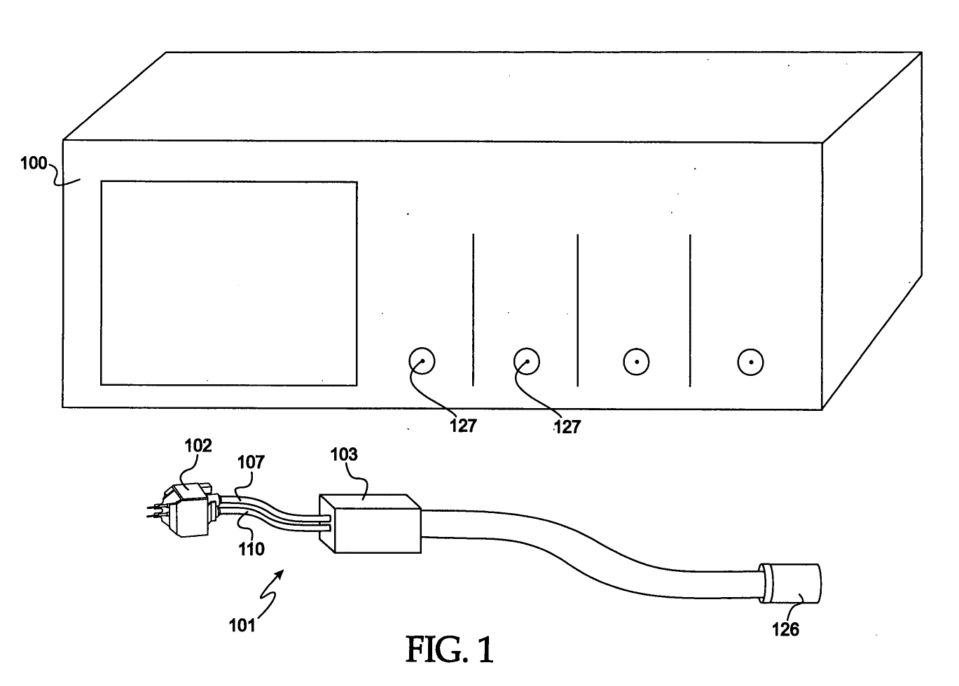

With specific reference to FIG. 1 of the drawings, there is shown a probing system 101 according to the present teachings in proximity to a measurement device 100 to which the probing system 101 may be connected and used for purposes of measuring electrical signals. The illustration of FIG. 1 shows an oscilloscope as the measurement device 100, but one of ordinary skill in the art appreciates that any electronic device that measures electrical signals may be used. The probing system 101 has a probe head 102 and first and second probe cables 107, 110 connecting the probe head 102 to amplifier 103. In a specific embodiment, the probe cables 107, 110 are 50 ohm coaxial cables. As such, it is desirable to maintain the entire length of the probing system at a 100 ohm differential impedance. The probing system of the present teachings may be adapted to different impedance specifications by one of ordinary skill in the art.

In one embodiment of the probing system according to the present teachings, the probe head 102 and first and second probe cables 107, 110 are adapted to be connected to the amplifier 103. So as to not limit the bandwidth of the probing system, therefore, the connection between the first and second probe cables 107, 110 and the amplifier 103 is made via any connector style having a bandwidth at least as high as the probing system. Because, it is possible to less expensively manufacture the probe head 102 and cables 107, 110 than the entire probing system, a user of the probing system 101 may dedicate a plurality of probe heads 102 to the system under test and use only one or a smaller plurality of the amplifier 103 and supporting cables for connection to the measurement device 100 rendering the complete measurement system for the system under test less expensive without sacrificing measurement quality and bandwidth.

The amplifier 103 is connected to the measurement device via two coaxial cables and a measurement device connector 126. The measurement device 100 has a measurement device receiving connector 127 that mates with the measurement device connector 126 to provide a removeable and high quality electrical connection between the measurement device 100 and the probing system 101. DC power is also supplied by the measurement device 100 to power active circuitry in the amplifier 103.

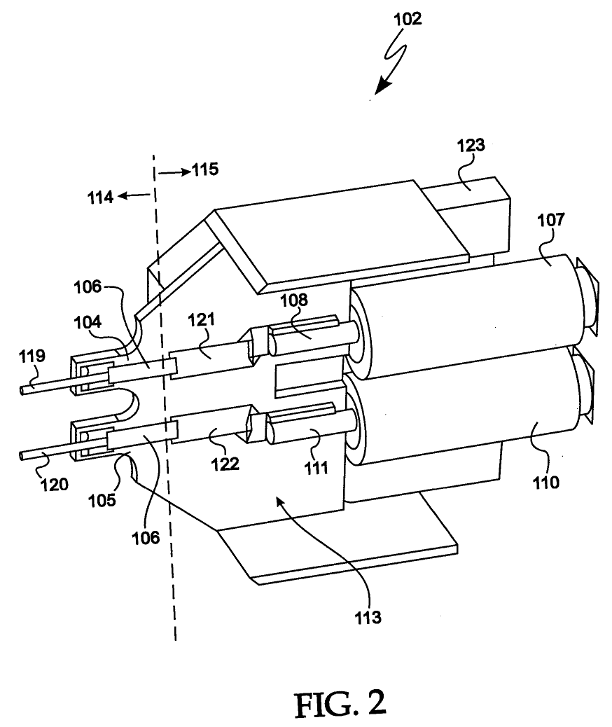

With specific reference to FIG. 2 of the drawings the probe head 102 has a probe head substrate 113 logically, though not necessarily physically separated into first and second portions 114, 115. The probe head substrate 113 may be made of a typical substrate material such as ceramic, alumina or alumina nitride. In a specific embodiment, the probe head substrate is an alumina 5-7 mils in thickness, which dissipates heat well relative to other possible substrate materials. In a specific embodiment, the probe head 102 is configured to maintain a constant impedance differential over the second portion 115 and minimizes capacitive loading by maximizing impedance over the first portion 114.

The first portion 114 of the probe head substrate 113 is adapted to form first and second cantilever members 104, 105 as a unitary part of the probe head substrate 113. The cantilever members 104, 105 are substantially parallel to each other. A gap between the cantilever members 104, 105 is configured to minimize capacitive loading for that portion of the probe system 102. In a specific embodiment, the cantilever members are spaced 40 mils apart from each other. For purposes of strength of the cantilever members 104, 105, there is a quarter rounded transition between each cantilever member 104 and 105 and the remainder of the probe head substrate 113.

Respective resistive elements 106 are affixed to each cantilever member 104 and 105. In a specific embodiment, the resistive elements 106 are thick film resistors printed onto the probe head substrate 113 and laser trimmed to achieve a desired resistance. Each resistive element 106 is electrically connected to respective first and second signal contact elements 119, 120. The first and second signal contact elements 119, 120 extend past an end of the respective cantilever elements 104, 105 on which the signal contact elements 119 or 120 is disposed. In a specific embodiment, the signal contact elements 119, 120 are made of nickel wire. In an application of a probe system 101 according to the present teachings, a free end of each signal contact element 119 or 120 may be soldered to a printed circuit board under test for purposes of probing a high frequency electrical signal for visibility on the measurement device 100 such as an oscilloscope. In a specific embodiment, the electrical connection between the resistive elements 106 and the respective signal contact elements 119, 120 is achieved via solder, although any suitable method for electrical connection may be used without departing from the present teachings. Beneficially, the solder that provides electrical connection between the resistive element 106 and the respective signal contact elements 119, 120 also provides mechanical connection of each signal contact element 119, 120 to the probe head substrate. Because it is contemplated that the signal contact elements 119, 120 are soldered to the printed circuit board or electrical circuit under test, it is further beneficial for the probe head substrate to be able to dissipate heat through the substrate so as to not heat up a junction between the resistive element and the signal contact element to the point where its solder joint reflows and separates. In an alternate application, the signal contact elements 119, 120 are not soldered to the system under test and are made of a spring material such as spring steel or tungsten where they may be used for browsing applications.

The first and second signal contact elements 119, 120 extend past a distal end of the cantilever members 104, 105 for purposes of probing the system under test. A non-signal contact end of the resistive elements 106 defines a rough delineation between the first and second portions 114, 115 of the probe head substrate 113. Each resistive element 106 is electrically connected to respective transmission lines 121, 122 disposed on the second portion 115 of the probe head substrate 113. In a specific embodiment, the first and second transmission lines 121, 122 are parallel to each other. Within the area of the probe head substrate 113 that is between the first and second transmission lines 121, 122, a portion is removed in order to maintain a constant differential impedance of the transmission lines 121, 122.

Each printed transmission line 121, 122 is disposed on the second portion 115 of the probe head substrate 113 and is electrically connected, such as by solder connection, to center conductors 108, 111 of respective coaxial first and second probe cables 107, 110. The center conductors 108, 111 are conductors of a coaxial cable that are exposed with the ground and shielding removed for the length of the remainder of the probe head substrate 113. As one of ordinary skill in the art can appreciate, therefore, two parallel series circuits are disposed on the probe head substrate 113 comprising the signal contact element 119 or 120, the resistive element 106, the transmission line 121 or 122, and the exposed center conductor of the coaxial probe cable 108 or 111.

A major surface of the probe head substrate 113 is disposed adjacent and parallel to a major surface of a probe head support element 123. In a specific embodiment, the probe head support element 123 is 25 mils in thickness and is made of the same material as the probe head substrate 113. As one of ordinary skill in the art appreciates, it is beneficial for a probe head to be small and light. This general benefit, however, is tempered by the additional need for durability and ease of handling. The probe head support element 123 provides support and stability for the junction between the probe cables 107, 110 and the probe head substrate 113 and also provides additional mass to the probe head of the probing system 102 for purposes of overall durability. The probe head support element 123 may be affixed to the probe head substrate 113 by any suitable means and in a specific embodiment is glued. The probe head support element 123 further comprises a ground plane as part of the major surface of the probe head support element 123 that is not adjacent the probe head substrate 113.

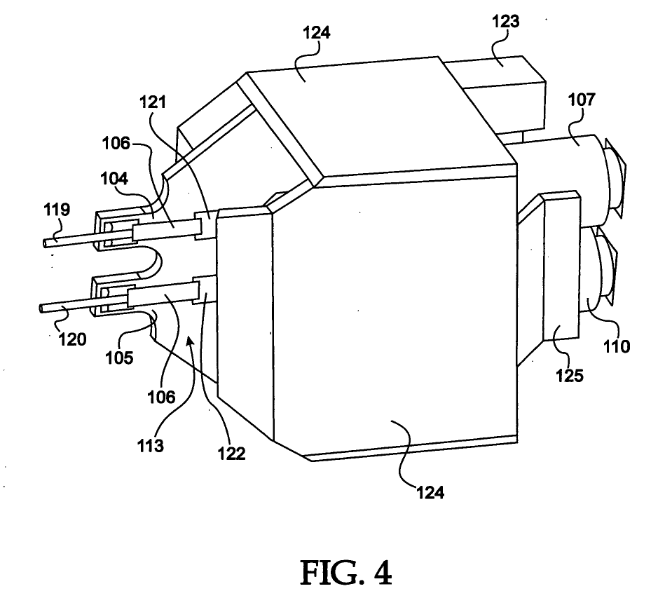

With specific reference to FIG. 4 of the drawings, there is shown a probe head shield 124. The probe head shield 124 is an electrically conductive shell that surrounds the probe head. The shield may be made of any suitable material and in a specific embodiment is made of nickel plated stainless steel. The probe head shield 124 comprises a flange element 125 that angles towards the shields without making contact. The flange element 125 may be soldered to the grounds of the first and second probe cables 107, 110.

Embodiments of the teachings are described herein by way of example with reference to the accompanying drawings describing a high bandwidth probing system. Other variations, adaptations, and embodiments of the present teachings will occur to those of ordinary skill in the art given benefit of the present teachings.

1. A probing system adapted for use with a measurement device comprising:
A probe head having a substrate shaped to form dual cantilever members, a resistive element disposed on each cantilever member and connected to respective signal contact elements, each resistive element electrically connected to respective center conductors of probe cables adapted for connection to the measurement device.

2. A probing system as recited in claim 1 further comprising an amplifier disposed between the resistive elements and the measurement device.

3. A probing system as recited in claim 1 wherein the substrate comprises first and second portions, the dual cantilever members and resistive elements being the first portion of the substrate and further comprising a support element adjacent the second portion of the substrate.

4. A probing system as recited in claim 1 and further comprising a grounded shield surrounding the probe head substrate.

5. A probing system as recited in claim 4 wherein the shield is electrically connected to the shields of the respective probe cables.

6. A probing system as recited in claim 1 wherein a channel is disposed between the respective center conductors.

7. A probing system as recited in claim 6 wherein the channel is sized and positioned to minimize capacitive loading.

8. A probing system as recited in claim 1 wherein the probe cables are coaxial transmission line cables.

9. A probing system as recited in claim 1 wherein the substrate is made from a material from the group of materials consisting of ceramic, alumina, alumina nitride, sapphire and glass.

10. A probing system as recited in claim 1 wherein the resistive elements are thick film resistors.

11. A probing system as recited in claim 10 wherein the thick film resistors are laser trimmed.

12. A measurement system comprising:
A measurement device and a probing system, the probing system having an amplifier and a probe head, the probe head comprising a substrate shaped to form dual cantilever members, a resistive element disposed on each cantilever member and connected to respective signal contact elements, each resistive element electrically connected to respective center conductors of probe cables adapted for connection to the measurement device.

13. A measurement system as recited in claim 12 wherein the amplifier is disposed between the resistive elements and the measurement device.

14. A measurement system as recited in claim 12 wherein the substrate comprises first and second portions, the dual cantilever members and resistive elements being the first portion of the substrate the probe head further comprising a support element adjacent the second portion of the substrate.

15. A measurement system as recited in claim 12 and further comprising a grounded shield surrounding the probe head substrate.

16. A measurement system as recited in claim 15 wherein the shield is electrically connected to the shields of the respective probe cables.

17. A measurement system as recited in claim 12 wherein a channel is disposed between the respective center conductors.

18. A measurement system as recited in claim 17 wherein the channel is sized and positioned to maintain a substantially constant differential impedance from the transmission lines to the center conductors.

19. A measurement system as recited in claim 12 wherein the probe cables are coaxial transmission line cables.

20. A measurement system as recited in claim 12 wherein the substrate is made from a material from the group of materials consisting of ceramic, alumina, alumina nitride, sapphire and glass.

21. A measurement system as recited in claim 12 wherein the resistive elements are thick film resistors.

22. A measurement system as recited in claim 21 wherein the thick film resistors are laser trimmed.
